(19) United States
(12) Patent Application Publication
(10) Pub. No.: US 2005/0149789 A1
(43) Pub. Date: Jul. 7, 2005

(54) Pseudo random verification of waveform fault coverage

(75) Inventor: Kevin Driscoll, Maple Grove, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc., Morristown, NJ (US)

(21) Appl. No.: 10/993,398

(22) Filed: Nov. 19, 2004

Related U.S. Application Data
(60) Provisional application No. 60/523,784, filed on Nov. 19, 2003.

(51) Int. Cl. G01R 31/28

(52) U.S. Cl. 714/724

(57) ABSTRACT

A verification of fault coverage tool for testing digital logic electronic components. In one embodiment, a method of testing a device under test (DUT) having an input and a plurality of redundant outputs is provided. The method comprises defining a logic test grid of test sample points that generally define an indeterminate logic range over a period of time. Generating a plurality of pseudo random test waveforms that are designed to pass though each test sample point and every sequential combination of test sample points. Coupling the plurality of pseudo random test waveforms to the input of the DUT. Reading the plurality of redundant outputs of the DUT for each of the plurality of pseudo random test waveforms coupled to the input of the DUT and determining the proof of coverage of the DUT in the indeterminate logic range based on the observing of the plurality of redundant outputs of the DUT.

### CROSS REFERENCE TO RELATED APPLICATIONS

This application is related to and claims the benefit of the filing date of U.S. Provisional Application No. 60/523,784, filed on Nov. 19, 2003, which is incorporated herein by reference.

### TECHNICAL FIELD

The present invention relates generally to fault coverage of devices in a circuit and in particular to proof of fault coverage of devices under test.

### BACKGROUND

Fault tolerant systems must provide a specified level of service after a fault has occurred. High criticality systems require that faults be tolerated that have a probability of occurrence between 10⁻⁹ to 10⁻⁶ for a one hour exposure. Typically the desired level of fault tolerances must be proven to be met by a combination of analysis and testing. The ability to detect and mitigate a fault is called coverage. The overall system failure probability includes the combination of component fault probability and coverage percentage. For electronic components (typically integrated circuits) used in the environment where highly dependable electronic systems are acquired, one assumes a component failure probability of 10⁻⁶ for a one hour exposure. Moreover, with multiple components in a system, one can assume an overall failure rate in the range 10⁻⁴ to 10⁻⁵ for a one hour exposure.

Byzantine faults comprise a class of faults that are particularly difficult cover. A Byzantine fault is a fault that presents different outputs to multiple observers. For example, in a logic circuit having an input and multiple redundant outputs, if different observers of the outputs observe different outputs in response to an input, a Byzantine fault is present. Even if the logic circuit has only a single output with multiple observers, each observer can view the output signal differently due to the behavior of a Byzantine fault. Byzantine faults occur in two dimensions, amplitude and time. Regarding amplitude, a Byzantine fault can cause signals traveling through elements in the logic circuit to not be clearly defined as a “logic 1” or a “logic 0.” These signals fall somewhere in between the signal level defined as logic 1 and logic 0. These so called “½ logic signals” or “indeterminate logic signals” can be interpreted by different elements in the logic circuits as either a logic 1 or a logic 0. However, not every element in the logic circuit will make the same determination. This is due to manufacturing variances in the logic devices or to such environmental factors as voltage variances and temperature variances. In the time dimension, Byzantine faults can occur in the micro and macro scale. In the micro scale, the faults occur at the bit level wherein the bits are formed too narrow or too wide. At the macro scale, Byzantine faults typically occur due to missing communication signal deadlines. Moreover, Byzantine faults occur more often in the time domain than in the amplitude domain.

For highly critical applications that require system failure probabilities in the neighborhood of 10⁻⁹ for a one hour exposure, methods have to be developed to handle the ½ logic signals. One method of dealing with Byzantine faults is with a filtering device that reshapes ½ logic signals to valid logic signals before the logic signal is observed by the observers. Once the Byzantine faults have been dealt with in a circuit design, proof of the design's fault coverage is required. However, current analysis and test methods for proving the correct operation of digital electronic circuits are not applicable to Byzantine fault filtering.

For the reasons stated above and for other reasons stated below which will become apparent to those skilled in the art upon observing and understanding the present specification, there is a need in the art for a method of providing proof of fault coverage for Byzantine fault filter designs in highly critical systems.

### SUMMARY

The above-mentioned problems and other problems are resolved by the present invention and will be understood by observing and studying the following specification.

In one embodiment, a method of providing proof coverage of a logic circuit is provided. The method comprises generating pseudo random test waveforms. Inputting the test waveforms into an input of the logic circuit and observing a plurality of redundant outputs of the logic circuit to determine the proof of coverage of the logic circuit.

In another embodiment, a method of testing a device under test (DUT) having an input and a plurality of redundant outputs is provided. The method comprises defining a logic test grid of test sample points on the DUT input that generally covers an indeterminate logic range over a period of time. Generating a plurality of pseudo random test waveforms that are designed to pass though each test sample point and every sequential combination of test sample points. Coupling the plurality of pseudo random test waveforms to the input of the DUT. Reading the plurality of redundant outputs of the DUT for each of the plurality of pseudo random test waveforms coupled to the input of the DUT and determining the proof of coverage of the DUT in the indeterminate logic range based on the observing of the plurality of redundant outputs of the DUT.

In yet another embodiment, a proof of coverage tester is provided. The proof of coverage tester includes a pseudo random waveform generator and an output tester. The pseudo random waveform generator is adapted to couple waveforms to an input of a device under test (DUT). The output tester is adapted to observe a plurality of redundant outputs of the DUT and to verify proof of coverage of the DUT based on the outputs.

In further yet another embodiment, a proof of coverage testing system is provided. The testing system including a pseudo random waveform generator, a digital to analog (D/A) converter and an output tester. The pseudo random waveform generator is adapted to generate pseudo exhaustive waveforms over a predefined grid. The D/A converter is coupled to an output of the pseudo random waveform generator. The D/A converter further has an output that is adapted to be coupled to a device under test (DUT). The output tester is adapted to observe a plurality of redundant outputs of the DUT and determine the proof of coverage of the DUT.

In still further another embodiment an output tester for a device under test (DUT) having multiple outputs is provided. The output tester comprises a pair of flip flops for each output of the DUT and a flip flop comparator for each pair of flip flops. Each flip flop in a pair of flip flops is adapted to output a logic level based on a sample of an associated output in which one of the flip-flops in the pair latches its sample of the output signal according to the maximum threshold voltage (the voltage at which a device determines a voltage to be one or zero) allowed over manufacturing and environmental variances and the other flip flop a latches its sample of the output signal according to the minimum threshold voltage allowed. Each flip flop comparator is adapted to compare the output logic levels of it associated pair of flip flops. Moreover, each flip flop comparator outputs a signal based on the comparison.

In finally another embodiment, a proof of coverage tester is provided. The tester includes a pseudo random waveform generator, a digital to analog (D/A) converter and an output tester. The pseudo random waveform generator is adapted to generate pseudo random waveforms. The digital to analog (D/A) converter is coupled to convert the pseudo random waveforms into analog waveforms. The D/A converter is further adapted to couple the analog waveforms to at least one input of a device under test (DUT). The output tester is adapted to observe a plurality of redundant outputs of the DUT and to verify proof of coverage of the DUT based on the observing of the plurality of redundant outputs.

### BRIEF DESCRIPTION OF THE DRAWINGS

The present invention can be more easily understood and further advantages and uses thereof more readily apparent, when considered in view of the description of the preferred embodiments and the following figures in which:

FIG. 1A is an example of a logic voltage level graph for logic devices in a logic circuit;

FIG. 1B is a logic gate transfer function graph illustrating the gain of a logic device in the ½ logic area;

FIG. 2 is a logic voltage level graph with a grid of test sample points of one embodiment of the present invention;

FIG. 3 is a logic voltage level graph with a test waveform of one embodiment of the present invention;

FIG. 4 is a block diagram of a test system of one embodiment of the present invention;

FIG. 5 is a flow chart illustrating one method of one embodiment of the present invention; and

FIG. 6 is a block diagram of a testing system of another embodiment of the present invention.

In accordance with common practice, the various described features are not drawn to scale but are drawn to emphasize specific features relevant to the present invention. Reference characters denote like elements throughout Figures and text.

### DETAILED DESCRIPTION

In the following detailed description of the preferred embodiments, reference is made to the accompanying drawings, which form a part hereof, and in which is shown by way of illustration specific preferred embodiments in which the inventions may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense, and the scope of the present invention is defined only by the claims and equivalents thereof.

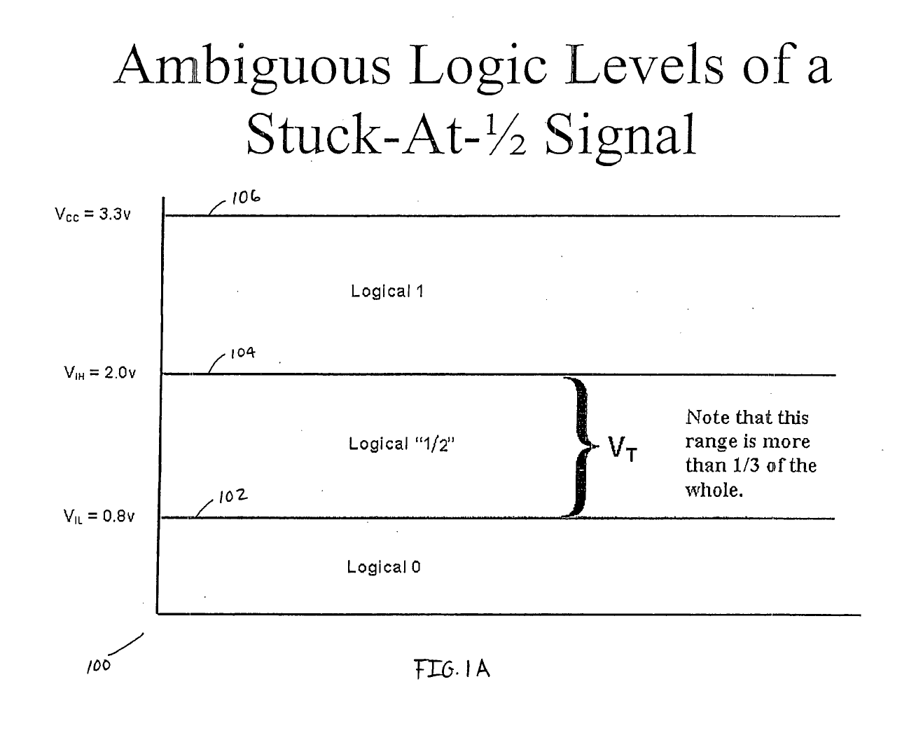

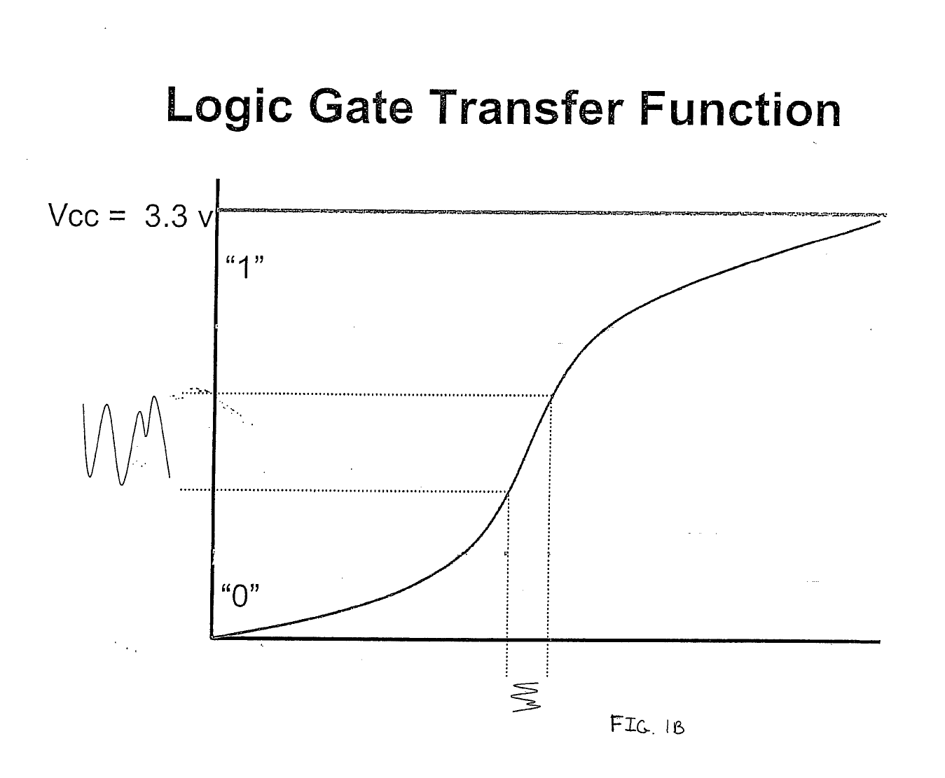

Embodiments of the present invention provide a method and a tool to provide proof of fault coverage that utilizes a pseudo random waveform generator and a V₂ logic grid. Before further description of embodiments of the present invention is provided in detail, additional background is given to aid in the understanding of the present invention. Referring to FIG. 1A, a logic voltage level graph 100 is illustrated. FIG. 1 is representative of a common logic family in use today and is illustrative of any logic family. Logic level graph 100 shows examples of voltages levels that make up a logic 0, a logic ½ and a logic 1 in logic devices of a circuit. The voltage input low (V_{IL}) 102 is the threshold voltage level below which all logic chips in a circuit will observe a logic 0. V_{IL} 102 in this example is 0.8 v. Voltage input high (V_{IH}) 104 is the threshold voltage level above which all logic chips in a circuit will observe a logic 1. V_{IH} 104 in this example is 2.0 v. Also illustrated in FIG. 1A is V_{CC} 106. V_{CC} is the voltage supply level which is 3.3 v in this example.

As indicated in FIG. 1A, the area between V_{IL} 102 and V_{IH} 104 is the logical ½ region or area. This can also be referred to as the indeterminate region or area. This is the area where it cannot be determined for certain whether a logic circuit will observe the signal as a logic 1 or a logic 0. As indicated, in this example, the indeterminate region makes up more than ⅓ of the voltage range. Therefore, there is relatively wide range of indeterminate logic possibilities that have to be considered in determining proof of fault coverage. The present invention provides a method of testing how logic circuits will behave with signals in the indeterminate logic range. Referring to FIG. 1B, an illustration of a logic gate transfer function is provided. FIG. 1B is provided to show that in the indeterminate logic range, the gain of a logic device is relatively high. Therefore even a little input noise tends to cause relatively large output noise. As a result, instead of looking at DC levels, high frequency and large amplitude noise is typically observed. However, this is still considered to be within the indeterminate logic range because of the integrating effects of electronic circuits at those speeds.

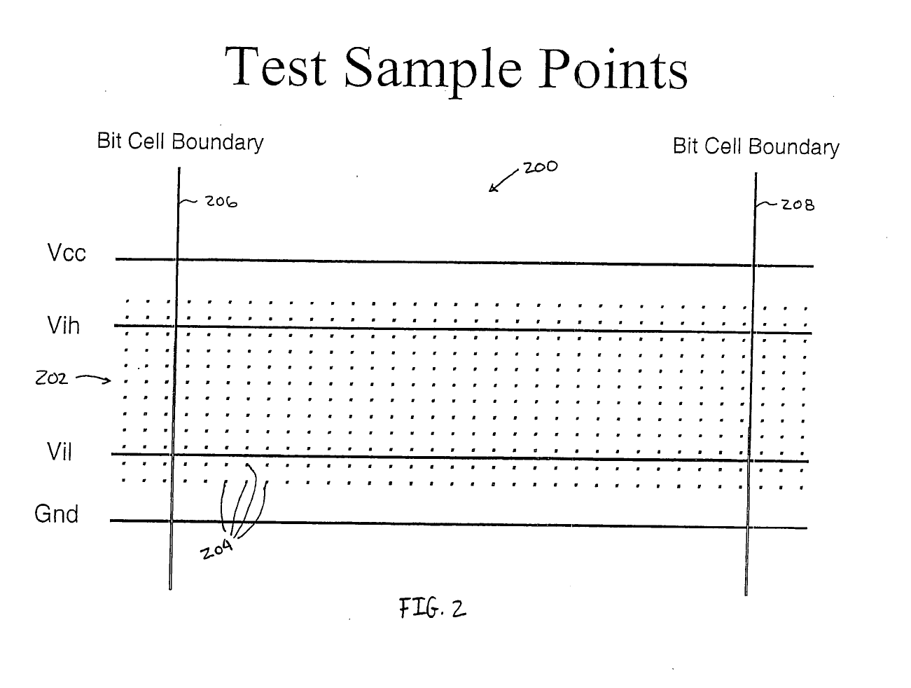

Embodiments of the present invention use a grid of test sample points in testing proof of coverage of a circuit. FIG. 2 illustrates a logic voltage level graph 200 with a logic level test grid 202 in one embodiment of the present invention. Grid 202 is made up of a plurality of test sample points 204 (or test points 204). The test sample points 204 in the horizontal (row) direction represent a time domain. The density of the test sample points 204 in the time domain direction is limited by the physics of a device under test (DUT). In particular, the distance between adjacent test sample points 204 in the horizontal direction is related to the maximum frequency a device can handle. For example, if the DUT can only handle a signal as fast as 250 pico seconds, the minimum distance between two adjacent test sample points in the horizontal direction will represent 250 pico seconds.

Each test sample point 204 in the vertical (column) direction represents a voltage level of a signal or waveform that is tested during a proof of fault coverage test. The density of the test sample points 202 in the vertical direction are determined by the desired thoroughness of the test and the linear and non-linear properties of the devices (or device) in the DUT. For example, devices that exhibit linear properties, like CMOS, allow for greater vertical distance between adjacent test sample points 204. In linear devices, it is understood that once the behavior of these devices is determined at two end points, the behavior in between the two end points is also known due to their linearly nature. With linear devices, consistency in the grid is a significant attribute in designing an effective grid. In regards to non-linear devices, their needs to be sufficient test sample points 204 in the vertical direction to cover all non-linearity's that are the result of inflections in the transfer functions of the non-linear device. For example, a simple gate not only performs its designed logic, it also acts as an amplifier. The voltage in and voltage out follows some kind of transfer curve. If the transfer curve is non-linear, the test sample points are placed at every high and low point. FIG. 2 also illustrates cell boundaries 206 and 208. The cell boundaries 206 and 208 indicate the period of time between one data transition to another data transition which is determined by a clock frequency.

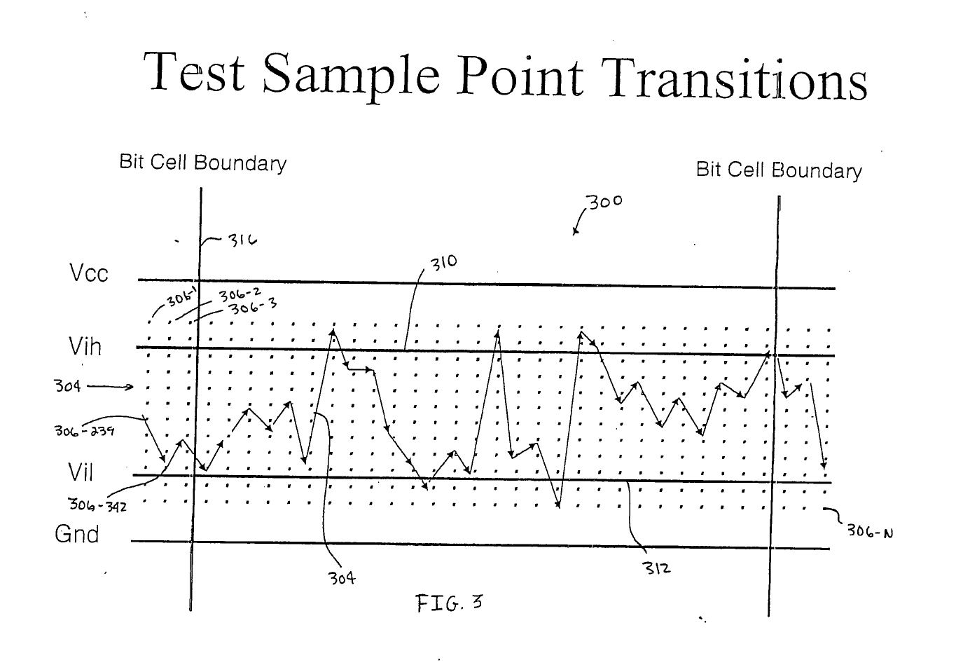

Referring to FIG. 3, an example of a logic level graph 300 with a grid 302 and a waveform 304 using the grid 302 of test sample points 306-1 through 306-N is illustrated. This embodiment illustrates how the waveform 304 is formed from one test sample point to the next sample point in the grid 302. For example, the first leg of the waveform 304 is formed between test sample points 306-239 and 306-342. As illustrated in this embodiment, some test sample points are located above the V_{IH} voltage level 310 and some test sample points are located below the V_{IL} voltage level 312. This allows for different shaped waveforms 304 that can extend beyond and back into the indeterminate logic area. Moreover, this embodiment also illustrates that the waveforms can be started before the bit cell boundary 316, which allows for the set up of initial conditions.

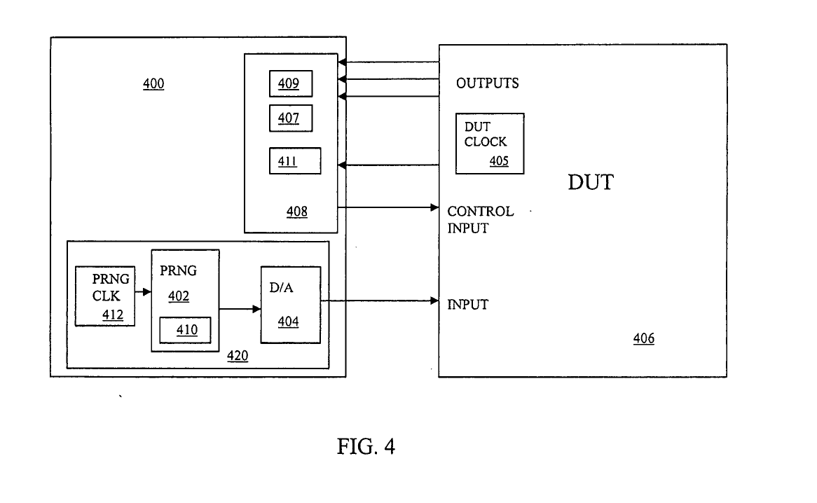

To complete a test, pseudo random waveforms are applied to the logic circuit (or DUT) being tested. One embodiment of a test system 400 of the present invention is illustrated in FIG. 4. Test system 400 includes a pseudo waveform generator 420. In this embodiment, the pseudo waveform generator includes a clock 412, a pseudo random number generator (PRNG) 402 and a digital to analog (D/A) converter 404. As illustrated, an output of the PRNG 402 is coupled to the D/A converter 404. An output of the D/A converter 404 is coupled to an input of a DUT 406. In one embodiment, the D/A converter 404 is a multi-bit D/A converter. In this embodiment, a plurality of sequentially contiguous bits from the PRNG 402 are passed through the multi-bit D/A converter 404 to the input of the DUT. In one embodiment the D/A converter 404 is a R-2R resister ladder. In another embodiment, the D/A converter 404 is a low pass filter. In this embodiment, a low pass filter (such as a capacitor—resistor low pass filter) performs a rudimentary D/A converter when passing the bits from the PRNG 402 (which is used as a pulse width modulated signal) to the input of the DUT 406. Moreover, in one embodiment, the low pass filter is merely the intrinsic characteristics on the input port of the DUT 406. Further yet in another embodiment, the D/A converter 404 is a combination of a multi-bit D/A converter and a low pass filter. This embodiment, provides additional levels of precision.

As illustrated, a plurality of redundant outputs of the DUT 406 are coupled to an output tester 408. The output tester 408 is adapted to determine the fault coverage of the DUT 406 by observing the outputs of the DUT 406 in response to the pseudo random waveforms applied to the input of the DUT 406. In particular, in this embodiment, the output tester 408 includes control circuitry 409 that is adapted to observe the plurality of outputs, compare the outputs and store statistics regarding counts of matching, non-matching, and indeterminate outputs for each pseudo random waveform applied to the input of the DUT 406 in memory 407. Moreover, control circuitry 409 is further adapted to determine the fault coverage of the DUT by comparing the stored counts of match the non-matched and indeterminate data in the memory 407 upon completion of a test. The outputs of the DUT 406 need not be bit by bit identical. For example, some of the outputs could be designed to be inverts of the other outputs. The output tester 408, in embodiments of the present invention, are adapted to take this into consideration in determining matching and non-matching data. In addition, the control circuitry 409 is adapted to control functions of the DUT 406 through an optional set of control inputs, for those DUTs which may need them. These controls include such things as output enables, resets, voltage operating levels, operating frequencies levels and the like. This allows the testing of the DUT under different conditions.

As stated above, to ensure coverage, the test waveforms must cover every test sample point in a grid and every possible sequential combination of test sample points in the grid. In one embodiment, the PRNG 402 accomplishes this with at least one linear feedback shift register (LFSR) 410 using primitive polynomials as the feedback. As illustrated in FIG. 4, the LFSR 410 is driven by a clock signal from clock 412. By using a linear feedback shift register 410 with primitive polynomials as the feedback, it is guaranteed that all test sample points will occur and all sequential combinations will occur up to the size of the shift register. Examples of shift register sequences can be found in Golumb's, Shift Register Sequences, published by Aegean Park Press, 1982.

The amplitude grid spacing is determined by the length of the contiguous bit sequences extracted from LFSR 410 and sent to the D/A converter and the relation of bit width to the time constant of the low pass filter. To eliminate amplitude correlations from one time step to the next, the extracted LFSR bit sequences should not overlap. The longer the LFSR 410, the longer the unique and uncorrelated sequence of test points that can be created. However, the more test points, the longer it will take to complete the test. Therefore, there is a trade off between the length in time the testing requires and the thoroughness of the test. To provide a better understanding of the present invention, a grid example requiring 16 levels in amplitude is herein provided. In this example, four bits are taken out of the LFSR 410 at a time. Accordingly, in this embodiment, the LFSR 410 is clocked 4 times faster than the DUT is run. For example, the LFSR clock 412 may be running at 1 Giga Hertz while the DUT runs at 250 Mega Hertz.

In another embodiment of the present invention, the PRNG 402 includes four similar LFSRs 410. In this embodiment, each of the LFSRs 410 uses the same feedback polynomial and are started ¼ of the way through the sequence (i.e. the LFSRs are staggered). The outputs of the four LFSRs 410 of this embodiment are then fed into the D/A converter 404 which in turn provides the inputs for the DUT 406. The advantage of this embodiment is that the LFSRs can be run at the same clock rate as the DUT. In one embodiment, for each digital to analog input bit, a bit from each of the LFSR's are XOR'ed together.

Although, the D/A 404, the output tester circuit 408 and clock 412 are illustrated as being internal to the tester 400 in FIG. 4, other embodiments of the present invention have these devices external to the tester 400. For example, in other embodiments, a clock signal that operates the one or more LFSRs 410, are supplied externally to the respective devices. Likewise, in other embodiments the D/A 404 and/or the output tester 408 are external to the tester 400. In one embodiment, a clock 411 used to sample the DUT's outputs is coordinated with a clock 405 of the DUT such that the DUT's outputs are not sampled at the points in time when the DUT is changing them.

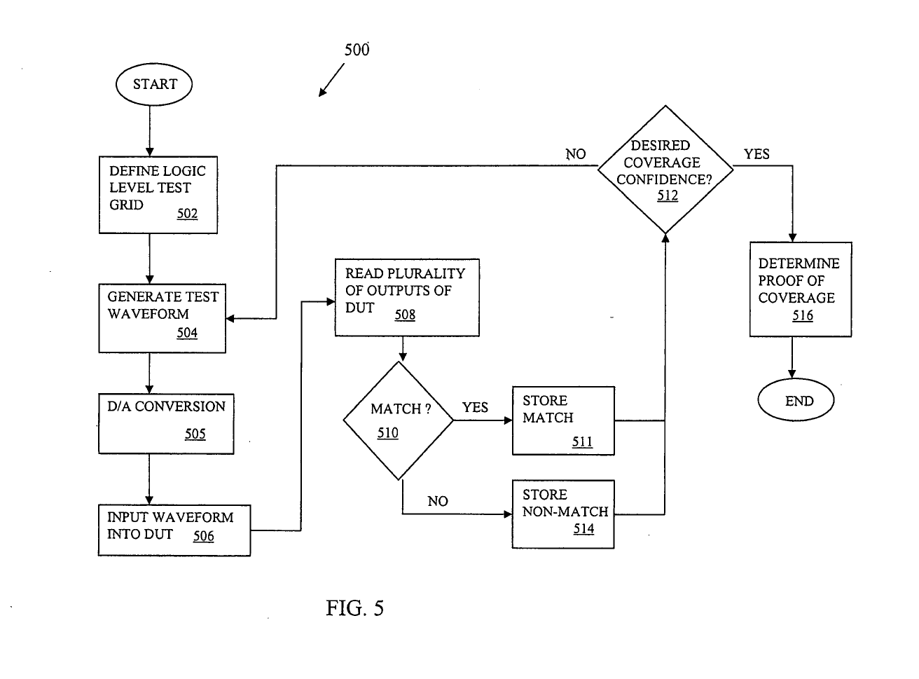

Referring to FIG. 5, a flow chart 500 illustrating one method of proof verification of the present invention is illustrated. As illustrated, in this embodiment, the method is started by first defining a logic level test grid (502). As discussed above, the logic level test grid sets out test sample points to be tested. A waveform is then generated that covers select test points in the logic level test grid (504). Embodiments of the present invention use a pseudo random waveform generator to generate the waveforms. In particular, in one embodiment, digital signals (from one or more linear feedback shift registers) are converted to an analog signal (505) to form the waveform. Each waveform is then inputted into an input of a DUT (506). A plurality of redundant outputs of the DUT are then observed in response to the input (508). The outputs are compared with each other to determine if they all match (510). If all the outputs match (510), data regarding match count statistics is stored in a memory (511). If all the outputs in response to an input do not match (510), data regarding non-match count statistics is stored in a memory (514).

It is then determined if all the possible test sample points and sequential combinations of test sample points in the logic test grid have been covered (512). In one embodiment, determining if all test sample points and sequential combinations of test sample points have been covered is done by tracking the number of signals the pseudo random number generator has produced and comparing the number with a predetermined number that generally guarantees that every possible test sample point and every possible sequential test sample points over a time period has occurred. In another embodiment, the value of the LFSR's internal state is examined. If the state is the same as the original state and a primitive feedback polynomial is used, the LFSR has gone through all possible internal states. In one embodiment, once an end of the test waveforms is determined, an end-of-test processing is performed. The determination of the number of waveforms to apply is determined by the length of the LFSR in use which in turn is related the number of test sample points in the test grid. In this embodiment, you determine the number of waveforms to apply by multiplying the number of test sample points in a vertical column by the number of test sample points in the next sequential vertical column and so on. For example, if you have 14 test sample points in a horizontal row and there are 16 test sample points in each vertical column, the number of waveforms to apply to the DUT in this example is determined by the equation 16¹⁴.

Referring back to FIG. 5, if all the test points and combinations have not been covered (512), the process continues at step 504 by generating another waveform (504). Once it has been determined that all the test points and combinations have been covered at step 512, the proof of coverage of the DUT is calculated and displayed (516). In one embodiment, this is done by observing the statistics of match, un-match and indeterminate data in the memory and then comparing the total amount of the matches with the total number of non-matches and indeterminants reported.

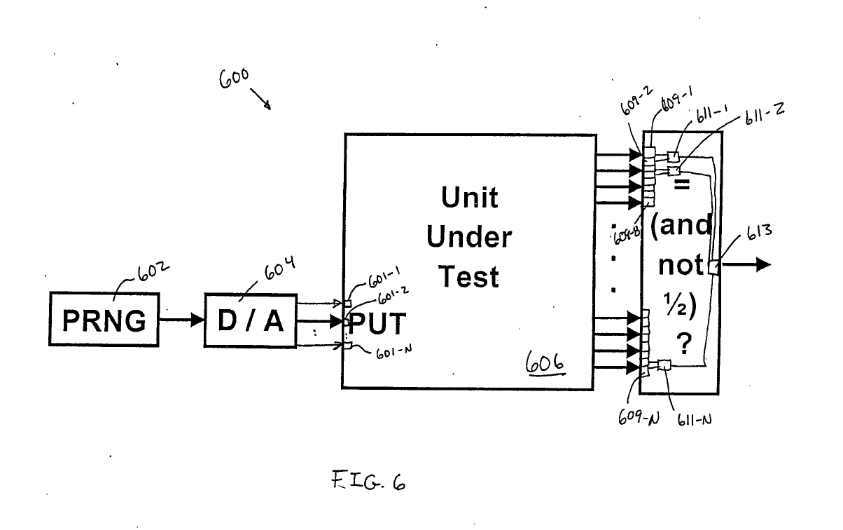

FIG. 6 illustrates a test system 600 of another embodiment of the present invention. As illustrated, the test system includes a pseudo random number generator 602, a digital to analog converter 604 and an output tester circuit 608. The pseudo random number generator 602 is adapted to generate pseudo random waveforms. The digital to analog converter is adapted to convert the digital pseudo random waveform into analog signals. The converted pseudo random waveforms are applied to at least one input of a DUT 606. In this embodiment, the DUT has multiple inputs 601 (1-N) that can be tested simultaneously. In this multiple input embodiment, the waveforms are guaranteed not to be correlated or to have some fixed known correlation as required by the DUT. The outputs of the DUT are coupled to the output tester circuit 608. The output tester circuit 608 is adapted to output a result of the comparisons of the outputs of the DUT. A verified output of the output test circuit 608 will occur when all of the outputs match and the matched outputs are not in the ½ logic (or indeterminate logic) range. In one embodiment, the output test circuit 608 includes a plurality of flip flops 601 (1-N). In one embodiment, two flip flops are coupled to each output of the DUT 606. If after taking samples close together of an output of the DUT by two associated flip flops 609, the flip flops produce different values once they settle down, the logic level is determined to be in the indeterminate range and a verified output signal from the output test circuit 608 will not occur. In one embodiment, this is done with flip flop comparators 611 (1-N). Moreover, in one embodiment, all of the flip flops 609 (1-N) must agree for a verified output signal to be produced by the output test circuit 608. In one embodiment, this is done with an overall comparator 613. However, in an embodiment where the DUT 606 produces outputs with inverts, the output test circuit is adapted accordingly. For example, the test circuit 608 in this embodiment can be adapted to invert the inverts before or after they are applied to the flip flops.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

1. A method of providing proof coverage of a Byzantine fault tolerance logic circuit, the method comprising:
generating pseudo random test waveforms;
inputting the test waveforms into at least one input of the logic circuit; and
observing a plurality of redundant outputs of the logic circuit to determine the proof of coverage of the logic circuit.

2. The method of claim 1, further comprising:
storing statistics regarding a count of matching and non-matching outputs; and
determining proof of coverage based on the stored count of matching, non-matching and indeterminate outputs.

3. The method of claim 1, further comprising:
defining a logic test grid of test sample points, wherein the test waveforms are adapted to cover all the test sample points and possible sequential combinations of test sample points.

4. The method of claim 3, wherein defining the logic test grid further comprises:
defining a indeterminate logic vertical range to be covered by the logic test grid; and
defining the vertical distance between each test sample point to represent a select voltage range.

5. The method of claim 4, wherein the closeness of the distance between adjacent vertical test sample points is determined by the non-linear properties of devices in the logic circuit.

6. The method of claim 4, further comprising:
defining further select test sample points of the logic test grid that extend beyond the defined indeterminate logic vertical range.

7. The method of claim 3, wherein defining the logic test grid further comprises
defining an indeterminate logic horizontal range to be covered by the logic grid; and
defining the horizontal distance between each test sample point to represent a select period of time.

8. The method of claim 7, wherein the closeness of the distance between horizontal test sample points is determined by the highest frequency each the logic circuit can handle.

9. The method of claim 7, further comprising:
defining further select test sample points of the logic test grid that occur before a defined bit cell boundary to allow for he initial set up of the pseudo random waveforms.

10. The method of claim 1, further comprising:
using a pseudo random number generator to generate the pseudo random waveforms.

11. The method of claim 10, wherein using the pseudo random number generator further comprises;
generating a pseudo exhaustive set of waveforms that guarantee the coverage of every test sample point and sequential combination thereof.

12. The method of claim 10, wherein the pseudo random number generator includes one or more feedback shift registers.

13. The method of claim 12, further comprising:
staggering the timing of the operation of one or more feedback shift registers in relation to each other.

14. The method of claim 12, further comprising:
creating digital signals with the one or more linear feedback shift registers, wherein primitive polynomials are used as the feedback to the one or more linear feedback shift registers.

15. The method of claim 14, further comprising:
converting the digital signals into analog signals.

16. The method of claim 15, wherein the converting of the digital signals into analog signals is done by a digital to analog converter.

17. The method of claim 15, wherein the converting of the digital signals into analog signals is done by an R-2R resister ladder.

18. The method of claim 12, further comprising:
outputting a plurality of sequentially contiguous bits from at least one of the one or more linear feedback shift registers; and
passing the plurality of sequentially contiguous bits through a multi bit digital to analog converter.

19. The method of claim 12, wherein the one or more linear feedback shift registers include multiple linear feedback shift registers coupled to a digital to analog converter, the method further comprising:
XORing a bit from each of the linear feedback shift registers together for each digital to analog converter input bit.

20. The method of claim 12, further comprising,
outputting bits from at least one of the one or more linear feedback registers; and
passing the bits through a low pass filter.

21. The method of claim 20, wherein the low pass filter is an intrinsic filter.

22. The method of claim 12, further comprising:
outputting a plurality of sequentially contiguous bits from at least one of the one or more linear feedback shift registers;
passing the plurality of sequentially contiguous bits through a multi bit digital to analog converter; and
passing the bits through a low pass filter.

23. A method of testing a device under test (DUT) having an input and a plurality of redundant outputs, the method comprising:
defining a logic test grid of test sample points on the input of the DUT that generally covers an indeterminate logic range over a period of time;
generating a plurality of pseudo random test waveforms that are designed to pass though each test sample point and every sequential combination of test sample points;
coupling the plurality of pseudo random test waveforms to the input of the DUT;
observing the plurality of redundant outputs of the DUT for each of the plurality of pseudo random test waveforms coupled to the input of the DUT; and
determining the proof of coverage of the DUT in the indeterminate logic range based on the observing of the plurality of redundant outputs of the DUT.

24. The method of claim 23, further comprising:
comparing the plurality of redundant outputs of the DUT;
storing a count of the number of matching and non-matching outputs; and
determining the proof of coverage of the DUT based on the count of matching and non-matching outputs.

25. The method of claim 23, further comprising:
synchronizing a sample clock to a clock of the DUT to avoid sampling the output when the DUT is changing.

26. The method of claim 23, wherein generating the plurality of pseudo random test waveforms further comprises:
clocking one or more linear feedback shift registers using a primitive polynomial as the feedback.

27. The method of claim 26, further comprising:
converting a digital signal from the one or more linear feedback registers to an analog signal.

28. The methods of claim 26, further comprising:
outputting a plurality of sequentially contiguous bits from at least one of the one or more linear feedback shift registers; and
passing the plurality of sequentially contiguous bits through a multi bit digital to analog converter.

29. The method of claim 26, further comprising,
outputting bits from at least one of the one or more linear feedback registers; and
passing the bits through a low pass filter.

30. The method of claim 26, further comprising:
outputting a plurality of sequentially contiguous bits from at least one of the one or more linear feedback shift registers;
passing the plurality of sequentially contiguous bits through a multi bit digital to analog converter; and
passing the bits through a low pass filter.

31. The method of claim 26, further comprising:
examining the internal state of each linear feedback shift resistor; and
if the internal state is the same as its original state, ending test waveform generation and performing end-of-test processing.

32. A proof of coverage tester comprising:
a pseudo random waveform generator adapted to couple waveforms to an input of a device under test (DUT); and
an output tester adapted to observe a plurality of redundant outputs of the DUT and to verify proof of coverage of the DUT based on the observing of the plurality of redundant outputs.

33. The proof coverage tester of claim 32, wherein the pseudo random waveform generator is adapted to generate test waveforms that cover all test sample points and sequential combinations of test sample points in a predefined logic level test grid.

34. The proof coverage tester of claim 32, wherein the output tester further comprising:
a memory adapted to store a count of match and non-match outputs per waveform coupled to the input of the DUT; and
control circuitry adapted to compare outputs of the DUT and to store the count of the match and non-match outputs in the memory, the control circuitry further adapted to determine the proof of coverage based on the stored count of matched and non-matched outputs.

35. The proof coverage tester of claim 32, wherein the pseudo random waveform generator further comprises:
a pseudo random number generator.

36. The proof of coverage tester of claim 32, wherein the pseudo random number generator further comprises:
one or more linear shift feedback registers using primitive polynomials as the feedback.

37. The proof of coverage tester of claim 36, further comprising:
a digital to analog (D/A) converter coupled to an output of the one or more linear shift feedback registers, the D/A converter further having an output that is adapted to be coupled to the DUT.

38. The proof coverage tester of claim 36, wherein the D/A converter further comprising:
a low pass filter.

39. The proof of coverage tester of claim 36, wherein the D/A converter further comprises:
a multi-bit D/A converter.

40. The proof of coverage tester of claim 39, further comprising:
a low pass filter coupled to the multi-bit D/A converter.

41. The proof coverage tester of claim 36, further comprising:
a clock to provide a clock signal to the one or more linear shift feedback registers at a select rate of speed.

42. The proof of coverage tester of claim 41, wherein the clocking of each of the one or more linear shift feedback registers is staggered with relation to the others of the one or more linear shift registers.

43. A proof of coverage testing system, the testing system comprising:
a pseudo random waveform generator adapted to generate pseudo exhaustive waveforms over a predefined grid;
a digital to analog (D/A) converter coupled to an output of the pseudo random waveform generator, the D/A converter further having an output that is adapted to be coupled to a device under test (DUT); and
an output tester adapted to observe a plurality of redundant outputs of the DUT and determine the proof of coverage of the DUT.

44. The testing system of claim 43, wherein the predefined grid comprises:
a defined indeterminate logic area of test sample points.

45. The testing system of claim 44, wherein the defined indeterminate logic area further comprises:
an indeterminate logic vertical range of test sample points having a vertical density limited by non-linear attributes of devices in the DUT; and
an indeterminate logic horizontal range of test sample test points having a horizontal density limited by the highest frequency the devices in the DUT can handle.

46. The testing system of claim 43, wherein the pseudo exhaustive waveforms cover every test sample point in the defined indeterminate logic area and every possible sequential combination of test sample points.

47. The testing system of claim 43, wherein the output tester is adapted to determine the proof of coverage of the DUT by comparing the plurality of redundant outputs of the DUT for each signal coupled to the input of the DUT.

48. The testing system of claim 43, wherein the output tester further comprises:
a memory; and
control circuitry adapted to observe the plurality of redundant outputs, the control circuitry further adapted to store statistics relating to the count of matching and non-matching outputs and provide the proof of coverage of the DUT based on the statistics upon observing the last of the outputs associated with a last waveform coupled to the input of the DUT.

49. The proof of coverage tester of claim 48, wherein the control circuitry is further adapted to control functions of the DUT.

50. The testing system of claim 43, further comprising:
one or more linear shift feedback registers using primitive polynomials as the feedback.

51. The testing system of claim 50, further comprising:
a tester clock adapted to provide a clock signal to clock the one or more shift feedback registers.

52. The proof of coverage tester of claim 51, wherein the clocking of each of the one or more linear shift feedback registers is staggered with relation to the others of the one or more linear shift registers.

53. An output tester for a device under test (DUT) having multiple outputs, the output tester comprising:
a pair of flip flops for each output of the DUT, each flip flop in a pair of flip flops adapted to output a logic level based on a sample of an associated output, wherein one of the flip-flops in the pair of flip flops latches its sample of the output signal according to the maximum threshold voltage allowed over manufacturing and environmental variances and the other flip flop latches its sample of the output signal according to the minimum threshold voltage allowed; and
a flip flop comparator for each pair of flip flops, each flip flop comparator adapted to compare the output logic levels of it associated pair of flip flops, where each flip flop comparator outputs a signal based on the comparison.

54. An output tester of claim 53, further comprising:
an overall comparator, adapted to compare the logic levels of all of the flip flop comparators and output a signal based on the comparison.

55. A proof of coverage tester, the tester comprising:
a pseudo random waveform generator adapted to generate pseudo random waveforms;
a digital to analog (D/A) converter coupled to convert the pseudo random waveforms into analog waveforms, the D/A converter further adapted to couple the analog waveforms to at least one input of a device under test (DUT); and
an output tester adapted to observe a plurality of redundant outputs of the DUT and to verify proof of coverage of the DUT based on the observing of the plurality of redundant outputs.

56. The tester of claim 55, wherein the output tester is further adapted to observe a plurality of redundant outputs wherein some of the outputs are inverts.

57. The tester of claim 55, wherein the D/A converter is at least one of a R-2R ladder, a low pass filter and an intrinsic integration characteristic of an input of the DUT.

58. The tester of claim 55, wherein the output tester is adapted to verify the plurality of redundant outputs when all the outputs are equal and are not all equal to an indeterminate voltage level.

59. The tester of claim 55, wherein the output tester further comprises:
a pair of flip flops for each output of the DUT, each flip flop in a pair of flip flops adapted to output a logic level based on a sample of an associated output; and
a flip flop comparator for each pair of flip flops, each flip flop comparator adapted to compare the output logic levels of it associated pair of flip flops, where each flip flop comparator outputs a signal based on the comparison.

60. The tester of claim 59, further comprising:
an overall comparator, adapted to compare the logic levels of all of the flip flop comparators and output a signal based on the comparison.
